(19) United States
(12) Patent Application Publication
(10) Pub. No.: US 2026/0018513 A1
(43) Pub. Date: Jan. 15, 2026

(54) Semiconductor Package Having a Die Assembly with an Electrically Insulating Thickness-Matching Layer

(71) Applicant: Infineon Technologies Austria AG, Villach (AT)

(72) Inventor: Achim Althaus, Regensburg (DE)

(21) Appl. No.: 18/769,747

(22) Filed: Jul. 11, 2024

(51) Int. Cl. H01L 23/528; H01L 21/768; H01L 23/495; H01L 23/522; H01L 29/20; H01L 29/778; H01L 29/78

(52) U.S. Cl. CPC H01L 23/5283; H01L 21/76802; H01L 21/76834; H01L 23/49568; H01L 23/5226; H10D 30/47; H10D 30/65; H10D 62/8503

(57) ABSTRACT

A semiconductor package includes a laminate package body and a die assembly embedded within the laminate package body. The laminate package body includes a plurality of laminate dielectric layers stacked on top of one another and metallization layers interposed between the laminate dielectric layers. The die assembly includes a thermally conductive substrate that includes a planar upper surface, a semiconductor die mounted on the planar upper surface of the thermally conductive substrate, and an electrically insulating thickness-matching layer formed on the planar upper surface of the thermally conductive substrate and surrounding the semiconductor die. An upper surface of the electrically insulating thickness-matching layer is substantially coplanar with an upper surface of the semiconductor die. The upper surface of the electrically insulating thickness-matching layer and the upper surface of the semiconductor die form an upper surface of the die assembly.

### BACKGROUND

A laminate semiconductor package, sometimes called an embedded package, typically includes some form of a die assembly embedded within a PCB-like structure of stacked dielectric and metallization layers, with outer layers of the laminate package body providing electrical and/or thermal contact with the semiconductor die(s) of the die assembly. A structure of the die assembly, e.g., a substrate, metallic body, lead frame, etc., may include one or more surface recesses or cavities that are structured to accommodate semiconductor die(s). The semiconductor dies may be electrically accessed by via structures and conductive tracks of the semiconductor body. The semiconductor die may be mounted on a metal substrate, which may act as a heat sink mechanism and/or provide a vertical electrical connection. While advantageous, this packaging technique presents challenges for semiconductor dies of different thickness. For example, forming a recess or cavity in a substrate to accommodate a thick semiconductor die may not be feasible using standard manufacturing methods. Alternative methods of accommodating such semiconductor dies may be cost prohibitive and/or increase manufacturing complexity.

Thus, there is a need for a simple, cost-effective solution for integrating thick semiconductor dies into laminate semiconductor packages.

### SUMMARY

According to an embodiment of a semiconductor package, the semiconductor package comprises: a laminate package body comprising a plurality of laminate dielectric layers stacked on top of one another and metallization layers interposed between the laminate dielectric layers; and a die assembly embedded within the laminate package body, wherein the die assembly comprises: a thermally conductive substrate that comprises a planar upper surface; a semiconductor die mounted on the planar upper surface of the thermally conductive substrate; and an electrically insulating thickness-matching layer formed on the planar upper surface of the thermally conductive substrate and surrounding the semiconductor die, wherein an upper surface of the electrically insulating thickness-matching layer is substantially coplanar with an upper surface of the semiconductor die, and wherein the upper surface of the electrically insulating thickness-matching layer and the upper surface of the semiconductor die form an upper surface of the die assembly.

According to an embodiment of a method of forming a semiconductor package, the method comprises: forming a die assembly by: mounting a semiconductor die on a planar upper surface of a thermally conductive substrate, and forming an electrically insulating thickness-matching layer on the planar upper surface of the thermally conductive substrate such that the electrically insulating thickness-matching layer surrounds the semiconductor die and an upper surface of the electrically insulating thickness-matching layer is substantially coplanar with an upper surface of the semiconductor die; forming a laminate package body by stacking a plurality of laminate dielectric layers and metallization layers on top of one another; and embedding the die assembly within the laminate package body by forming a central opening through one of the laminate dielectric layers and arranging the die assembly in the central opening.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a side cross-sectional view of a semiconductor package, according to an embodiment.

FIG. 2 illustrates a top plan view of a die assembly, according to an embodiment.

FIG. 3 illustrates a side cross-sectional view of a semiconductor package, according to an embodiment.

FIGS. 4A-4F illustrate a method of forming a semiconductor package, according to an embodiment.

### DETAILED DESCRIPTION

Described herein is a laminate semiconductor package, also known as an embedded package, comprising a die assembly embedded in a laminate package body of stacked dielectric and metallization layers. The die assembly includes a thermally conductive substrate having a planar upper surface on which a semiconductor die is mounted. An electrically insulating thickness-matching layer having the same thickness as the semiconductor die is formed on the planar upper surface and surrounds the mounted semiconductor die. Matching the thickness of the electrically insulating thickness-matching layer to the thickness of the semiconductor die provides the die assembly with a planar upper surface without protrusion of the semiconductor die. This configuration may simplify the process of embedding the die assembly into the laminate semiconductor package. Specifically, dielectric and metallization layers may be formed directly on the die assembly without the need to form openings in these layers to accommodate the semiconductor die.

Additionally, since the electrically insulating thickness-matching layer may be formed to any thickness, the configuration described herein may enable the laminate semiconductor package to include a sufficiently thick semiconductor die for which accommodating in a recess or cavity in the substrate is not feasible due to manufacturing limitations of forming such a recess or cavity. For example, the laminate semiconductor package described herein may include a GaN HEMT die having a thickness greater than 200 microns, or even greater than 250 microns, to be embedded into the laminate semiconductor package.

Thus, the solution disclosed herein may provide a cost-effective, relatively simple solution for integrating semiconductor dies, particularly thick semiconductor dies, into laminate semiconductor packages.

Described next, with reference to the figures, are exemplary embodiments of the semiconductor package.

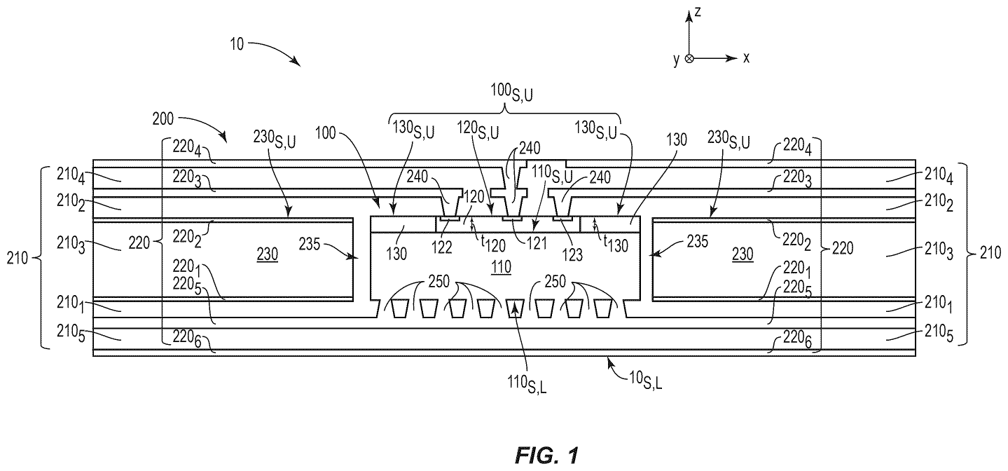

FIG. 1 illustrates a side cross-sectional view of a semiconductor package 10, according to an embodiment. The semiconductor package includes a laminate package body 200 and a die assembly 100 embedded within the laminate package body 200.

The laminate package body 200 includes a plurality of laminate dielectric layers 210 stacked on top of one another and metallization layers 220 interposed between the laminate dielectric layers 210. The laminate package body 200 may be formed using techniques that are similar to those used to form a printed circuit board (PCB). Each of the laminate dielectric layers 210 may include an electrically insulating material such as FR-4, FR-5, CEM-4, bismaleimide trazine (BT) resin, etc. One or more of the laminate dielectric layers 210 may be pre-formed. The metallization layers 220 may include a conductive metal such as copper (Cu), aluminum (Al), nickel (Ni), silver (Ag), palladium (Pd) gold (Au), etc., and alloys or combinations thereof. The metallization layers 220 can be structured to form internal interconnect lines within the laminate package body 200 as well as bond pads that are exposed at the outer surfaces of the semiconductor package 10. Each metallization layer 220 may be formed on the surface of a laminate dielectric layer 210, e.g. by a plating process, or may be a pre-formed layer that is bonded to a surface of a laminate dielectric layer 210. The laminate dielectric layers 210 may all be formed of the same material, or some or each of the laminate dielectric layers 210 may include different materials. Likewise, the metallization layers 220 may all be formed of the same material, or some or each of the metallization layers 220 may include different materials.

The laminate package body 200 includes a core structure 230 embedded between a first one 210₁ of the laminate dielectric layers 210 and a second one 210₂ of the laminate dielectric layers 210. In some examples, each of the first one 210₁ and the second 210₂ of the laminate dielectric layers 210 has a thickness from about 50 microns to about 100 microns, e.g., about 70 microns The die assembly 100 is arranged within a central opening 235 in the core structure 230 and is thus also embedded between the first one 210₁ of the laminate dielectric layers 210 and a second one 210₂ of the laminate dielectric layers 210. In the example of the semiconductor package 10 of FIG. 1, the core structure 230 includes a third one 210₃ of the laminate dielectric layers 210 (e.g., formed of a pre-preg material such as FR-4, FR-5, CEM-4) vertically between first and second ones 220₁ and 220₂ of the metallization layers 220. The third one 210₃ of the laminate dielectric layers may have a thickness greater than 1 millimeter, e.g., about 1.2 millimeters. Each of the first one 220₁ and the second one 220₂ of the metallization layers 220 may have a thickness from about 25 microns to about 50 microns, e.g., about 35 microns. The central opening 235 may be a preformed opening that is formed in the third one 210₃ of the laminate dielectric layers 210 before integrating the third one 210₃ of the laminated dielectric layers 210 into the laminate package body 200. The portion of the central opening 235 in the core structure 230 that surrounds the die assembly may be filled with a resin material such as bismaleimide triazine (BT) to encapsulate the die assembly 100.

The die assembly 100 includes a thermally conductive substrate 110 having a planar upper surface 110_{S,U}. The thermally conductive substrate 110 may be a monolithic structure, e.g. of a metal such as copper, aluminum, an alloy, etc., a part of a lead frame, or any other suitable substrate. In some examples, the thermally conductive substrate 110 includes multiple layers. Some examples of such a multilayered thermally conductive substrate 110 include a DCB (direct copper bonded) substrate, an AMB (active metal brazed) substrate, and an insulated metal substrate (IMS), among others.

A semiconductor die 120 is mounted on the planar upper surface 110_{S,U} of the thermally conductive substrate 110. The semiconductor die 120 may be formed in any device technology (transistor, diode, resistor, capacitor, another type of active or passive device) and may include any suitable semiconductor material. Examples of such materials include, but are not limited to, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGalnN) or indium gallium arsenide phosphide (InGaAsP), etc. The semiconductor die 120 may be configured as a transistor die such as a SiC or Si power MOSFET (metal-oxide-semiconductor field-effect transistor) device, a HEMT (high-electron mobility transistor) device, an IGBT (insulated-gate bipolar transistor) device, a JFET (junction filed-effect transistor) device, etc. In one embodiment, the semiconductor die 120 is configured as a GaN HEMT device. The semiconductor die 120 may include multiple of these and/or other devices. Examples in which multiple semiconductor dies 120 are mounted to the thermally conductive substrate 110 are contemplated. In the example of the semiconductor package 10 of FIG. 1, the semiconductor die 120 is configured as a lateral power transistor die having gate 121, source 122, and drain 123 terminals of the semiconductor die 120 that are disposed on an upper surface 120_{S,U} of the semiconductor die 120. This example is not limiting, however, and other configurations of the semiconductor die 120 are contemplated (e.g., a vertical power transistor).

The semiconductor die 120 has a thickness t₁₂₀ in the z direction of FIG. 1. In some embodiments, e.g., where the semiconductor die 120 is configured as a GaN HEMT device, the thickness t₁₂₀ of the semiconductor die 120 is at least 200 microns. In one embodiment, the thickness t₁₂₀ of the semiconductor die 120 is about 250 microns or more.

According to an embodiment, the die assembly 100 includes an electrically insulating thickness-matching layer 130 formed on the planar upper surface 110_{S,U} of the thermally conductive substrate 110 and surrounding the semiconductor die 120. The electrically insulating thickness-matching layer 130 has a thickness t₁₃₀ that is substantially the same as a thickness t₁₂₀ of the semiconductor die 120 plus a bond between the semiconductor die 120 (e.g., a solder joint) such that an upper surface 130_{S,U} of the electrically insulating thickness-matching layer 130 is substantially coplanar with the upper surface 120_{S,U} of the semiconductor die 120. For example, the semiconductor die 120 may have a thickness of about 250 and a bond between the semiconductor die 120 and the planar upper surface 100_{S,U} may have a thickness of about 25 microns. In this example, the thickness t₁₂₀ would be about 275 microns, and thus the corresponding electrically insulating thickness-matching layer 130 would also have thickness t₁₃₀ of about 275 microns. Together, the upper surface 130_{S,U} of the electrically insulating thickness-matching layer 130 and the upper surface 120_{S,U} of the semiconductor die 120 form an upper surface 100_{S,U} of the die assembly 100. In the example of the semiconductor package 10 of FIG. 1, the upper surface 100_{S,U} of the die assembly 100 is substantially coplanar with an upper surface 230_{S,U} of the core structure 230. The second one 210₂ of the laminate dielectric layers 210 is formed on (in some examples, directly on) the upper surface 230_{S,U} of the core structure 230 and the upper surface 100_{S,U} of the die assembly 100.

The electrically insulating thickness-matching layer 130 may be formed from of any electrically insulating material, e.g., a resin or other polymer, a polymer composite, etc. In some examples, the electrically insulating thickness-matching layer 130 is a molded layer formed of an electrically insulating mold compound. A mold compound is typically formed from an organic resin such as an epoxy resin and may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. In such examples, the electrically insulating thickness-matching layer 130 may be formed by injection molding, compression molding, film-assisted molding (FAM), reaction injection molding (RIM), resin transfer molding (RTM), blow molding, etc.

In the example of the semiconductor package 10 of FIG. 1, the second one 210₂ of the laminate dielectric layers 210 is interposed between a third one 220₃ of the metallization layers 220 and the upper surface 100_{S,U} of the die assembly 100. In some examples, the third one 220₃ of the metallization layers 220 has a thickness from about 100 microns to about 150 microns, e.g., about 129 microns. A plurality of electrically conductive vias 240 extend through the second one 210₂ of the laminate dielectric layers 210 and each electrically connect the third one 220₃ of the metallization layers 220 with a terminal of the semiconductor die 120 (e.g., the gate terminal 121, the source terminal 122, the drain terminal 123). The electrically conductive vias 240 may include electrically conductive metals such as copper, aluminum, tungsten, nickel, etc., and alloys or combinations thereof.

A fourth one 210₄ of the laminate dielectric layers 210 is interposed between the third one 220₃ of the metallization layers 220 and a fourth one 220₄ of the metallization layers 220. In some examples, the fourth one 210₄ of the laminate dielectric layers 210 has a thickness from about 50 microns to about 100 microns, e.g., about 70 microns. The fourth one 220₄ of the metallization layers 220 may, in some examples, have a thickness from about 50 microns to about 100 microns, e.g., about 66 microns. An additional electrically conductive via 240 extends through the fourth one 210₄ of the laminate dielectric layers 210 and electrically connects the fourth one 220₄ of the metallization layers 220 with one of the plurality of electrically conductive vias 240 that extend through the second one 210₂ of the laminate dielectric layers 210. Alternatively, this additional electrically conductive via 240 or another additional electrically conductive via 240 that extends through the fourth one 210₄ of the laminate dielectric layers 210 may electrically connect the fourth one 220₄ of the metallization layers 220 directly with a terminal of the semiconductor die 120 (e.g., the gate terminal 121, the source terminal 122, the drain terminal 123).

The first one 210₁ of the laminate dielectric layers 210 is interposed between a fifth one 220₅ of the metallization layers 220 and a lower surface 110_{S,L} of the thermally conductive substrate 110 that is opposite the planar upper surface 110_{S,U} of the thermally conductive substrate 110. A fifth one 210₅ of the laminate dielectric layers 210 is interposed between the fifth one 220₅ of the metallization layers 220 and a sixth one 220₆ of the metallization layers 220. In some examples, the fifth one 220₅ of the metallization layers 220 has a thickness from about 100 microns to about 150 microns, e.g., about 129 microns. In some examples, the fifth one 210₅ of the laminate dielectric layers 210 has a thickness from about 50 microns to about 100 microns, e.g., about 70 microns. In some examples, the sixth one 220₆ of the metallization layers 220 has a thickness from about 50 microns to about 100 microns, e.g., about 66 microns.

A plurality of thermally conductive vias 250 extend through the first one 210₁ of the laminate dielectric layers 210 and each thermally connect the fifth one 220₅ of the metallization layers 220 with the thermally conductive substrate 110. The lower surface 110_{S,L} of the thermally conductive substrate 110 is contacted by the thermally conductive vias 250. The thermally conductive vias 250 may include one or more materials having high thermal conductivity, e.g., copper, aluminum, tungsten, aluminum nitride, etc. The thermally conductive vias 250 may dissipate heat towards a lower surface 10_{S,L} of the semiconductor package 10.

The configuration of the laminate package body 200 of the semiconductor package 10 illustrated in FIG. 1 is not limiting. The laminate package body 200 may include fewer or any number of additional laminate dielectric layers 210, metallization layers 220, electrically conductive vias 240, and/or thermally conductive vias 250 than those illustrated. Additionally, the placement of the electrically conductive vias 240 and the thermally conductive vias 250 is not limited to the upper portion and the lower portion of the laminate package body 200, respectively.

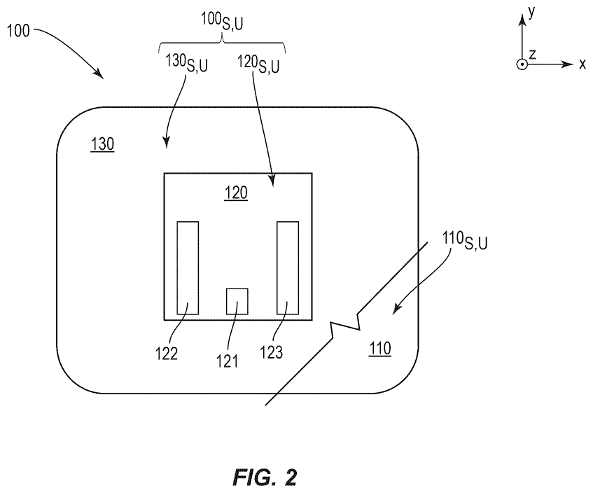

FIG. 2 illustrates a top plan view of the die assembly 100, according to an embodiment. A portion of the electrically insulating thickness-matching layer 130 is omitted to illustrate the electrically insulating thickness-matching layer 130 formed on the planar upper surface 110_{S,U} of the thermally conductive substrate 110. The electrically insulating thickness-matching layer 130 surrounds the semiconductor die 120. The upper surface 130_{S,U} of the electrically insulating thickness-matching layer 130 and the upper surface 120_{S,U} of the semiconductor die 120 form the upper surface 100_{S,U} of the die assembly 100.

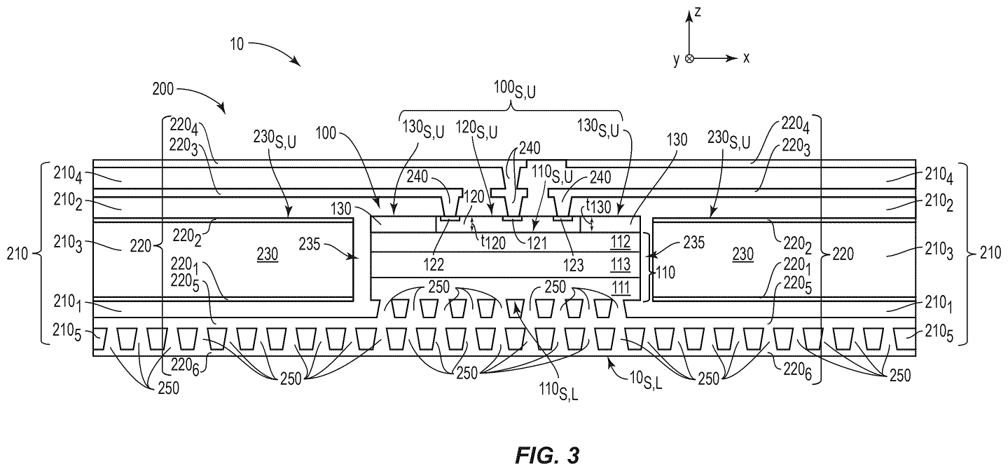

FIG. 3 illustrates a side cross-sectional view of the semiconductor package 10, according to an embodiment. The die assembly 100 of the semiconductor package 10 of FIG. 3 includes a thermally conductive substrate 110 that includes a ceramic layer 113 interposed between a first substrate metallization layer 111 and a second substrate metallization layer 112. The thermally conductive substrate 110 of this example may be a DCB or AMB substrate. The ceramic layer 113 may include aluminum nitride, aluminum oxide, silicon nitride, combinations thereof, etc. Each of the first substrate metallization layer 111 and the second substrate metallization layer 112 may include copper, aluminum, an alloy, etc. A plurality of thermally conductive vias 250 extend through the fifth one 210₅ of the laminate dielectric layers 210 and each thermally connect the sixth one 220₆ of the metallization layers 220 with the fifth one 220₅ of the metallization layers 220.

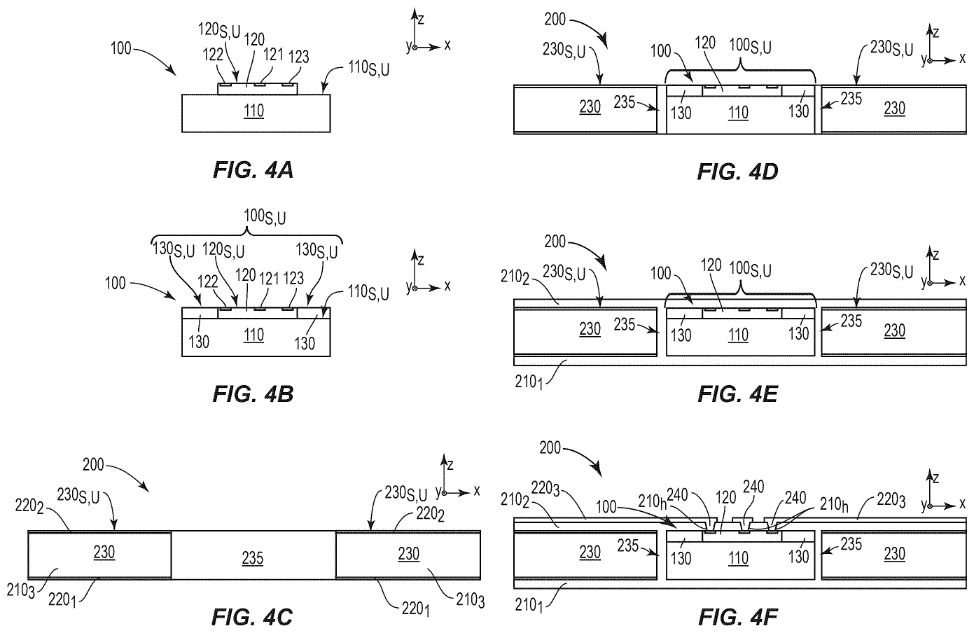

FIGS. 4A-4F illustrate a method of forming the semiconductor package 10, according to an embodiment.

FIGS. 4A-4B illustrate forming the die assembly 100. FIG. 4A illustrates mounting the semiconductor die 120 on the planar upper surface 110_{S,U} of the thermally conductive substrate 110. The semiconductor die 120 may be mounted on the planar upper surface 110_{S,U} of the thermally conductive substrate 110 by soldering (e.g., diffusion soldering, soft soldering), sintering (e.g., Ag or Cu sintering, hybrid sintering), brazing, welding, adhering, gluing, etc.

FIG. 4B illustrates forming the electrically insulating thickness-matching layer 130 on the planar upper surface 110_{S,U} of the thermally conductive substrate 110. The electrically insulating thickness-matching layer 130 is formed to surround the semiconductor die 120. The upper surface 130_{S,U} of the electrically insulating thickness-matching layer 130 is substantially coplanar with an upper surface 120_{S,U} of the semiconductor die 120. As noted previously, the electrically insulating thickness-matching layer 130 may be formed by a molding process such as injection molding, compression molding, film-assisted molding (FAM), reaction injection molding (RIM), resin transfer molding (RTM), blow molding, etc. In some examples, forming the electrically insulating thickness-matching layer 130 on the planar upper surface 110_{S,U} of the thermally conductive substrate 110 includes applying a resin, liquified mold compound, etc. onto the planar upper surface 110_{S,U} and curing, solidifying, etc. to form the electrically insulating thickness-matching layer 130. The partial die assembly 100 comprising the semiconductor die 120 mounted on the thermally conductive substrate 110 may be placed in a mold, and a liquified mold compound may be injected into the mold to form the molded electrically insulating thickness-matching layer 130. In some examples, forming the electrically insulating thickness-matching layer 130 on the planar upper surface 110_{S,U} of the thermally conductive substrate 110 includes preforming the electrically insulating thickness-matching layer 130 (e.g., by molding) and attaching the electrically insulating thickness-matching layer 130 to the planar upper surface 110_{S,U} of the thermally conductive substrate 110, e.g., by gluing, adhering, etc.

FIGS. 4C-4F illustrate forming the laminate package body 200 by stacking the plurality of laminate dielectric layers 210 and metallization layers 210 on top of one another. As noted in the description of FIG. 1, the laminate package body 200 may be formed using techniques that are similar to those used to form a printed circuit board (PCB). FIGS. 4D-4F illustrate embedding the die assembly 100 within the laminate package body 200.

FIG. 4C illustrates forming the core structure 230. The central opening 235 is formed through forming a central opening 235 through the one 210₃ of the laminate dielectric layers 210. The first one 220₁ and second one 220₂ of the metallization layers 220 are formed on opposing sides of the third one 210₃ of the laminate dielectric layers.

FIG. 4D illustrates arranging the die assembly 100 in the central opening 235 through the core structure 230 such that the upper surface 100_{S,U} of the die assembly 100 is substantially coplanar with the upper surface 230_{S,U} of the core structure 230. In this step, the part of the laminate package body 200 may be provided on an external carrier (not shown) and the die assembly 100 may be provided within the central opening 235. Portions of the central opening 235 that are not occupied by the die assembly 100 may be filled with a resin (e.g., bismaleimide triazine) or other material to laterally encapsulate the die assembly 100.

FIG. 4E illustrates embedding the core structure 230 and the die assembly 100 between the first one 210₁ of the laminate dielectric layers 210 and the second one 210₂ of the laminate dielectric layers 210. The first one 210₁ and the second one 210₂ of the laminate dielectric layers 210 may be preformed and adhered to the core structure 230 and the die assembly 100. In the example illustrated in FIG. 4E, the second one 210₂ of the laminate dielectric layers 210 is formed directly on (e.g., adhered to) the upper surface 230_{S,U} of the core structure 230 and the upper surface 100_{S,U} of the die assembly 100.

FIG. 4F illustrates forming the plurality of vias 240. The plurality of vias 240 may be formed by electroplating, electroless plating, or another method of deposing metal in holes 210ₕ formed in the second one 210₂ of the laminate dielectric layer 210. The holes 210ₕ may be preformed with the second one 210₂ of the laminate dielectric layer 210 or may be formed after forming the second one 210₂ of the laminate dielectric layers 210 on the upper surface 230_{S,U} of the core structure 230 and the upper surface 100_{S,U} of the die assembly 100. For example, the holes 210ₕ may be formed by a lithography process and subsequent etch process. A similar process may be used to form the thermally conductive vias 250 illustrated in FIGS. 1 and 3.

The steps of FIGS. 4E and 4F may be repeated to form additional laminate dielectric layers 210, metallization layers 220, electrically conductive vias 240, and/or thermally conductive vias 250 of the laminate package body 200.

Although the present disclosure is not so limited, the following numbered examples demonstrate one or more aspects of the disclosure.

Example 1. A semiconductor package, comprising: a laminate package body comprising a plurality of laminate dielectric layers stacked on top of one another and metallization layers interposed between the laminate dielectric layers; and a die assembly embedded within the laminate package body, wherein the die assembly comprises: a thermally conductive substrate that comprises a planar upper surface; a semiconductor die mounted on the planar upper surface of the thermally conductive substrate; and an electrically insulating thickness-matching layer formed on the planar upper surface of the thermally conductive substrate and surrounding the semiconductor die, wherein an upper surface of the electrically insulating thickness-matching layer is substantially coplanar with an upper surface of the semiconductor die, and wherein the upper surface of the electrically insulating thickness-matching layer and the upper surface of the semiconductor die form an upper surface of the die assembly.

Example 2. The semiconductor package of example 1, wherein the laminate package body comprises a core structure embedded between a first one of the laminate dielectric layers and a second one of the laminate dielectric layers, wherein the die assembly is arranged within a central opening in the core structure, and wherein the upper surface of the die assembly is substantially coplanar with an upper surface of the core structure.

Example 3. The semiconductor package of example 2, wherein the second one of the laminate dielectric layers is formed directly on the upper surface of the core structure and the upper surface of the die assembly.

Example 4. The semiconductor package of example 2 or 3, wherein the core structure comprises a third one of the laminate dielectric layers vertically between first and second ones of the metallization layers.

Example 5. The semiconductor package of any of examples 1 through 4, wherein the semiconductor die is configured as a lateral power transistor die, and wherein gate, source and drain terminals of the semiconductor die are disposed on the upper surface of the semiconductor die.

Example 6. The semiconductor package of example 5, wherein the semiconductor die is configured as a GaN HEMT device.

Example 7. The semiconductor package of any of examples 1 through 6, wherein a second one of the laminate dielectric layers is interposed between a third one of the metallization layers and the upper surface of the die assembly, and wherein the semiconductor package further comprises a plurality of electrically conductive vias that extend through the second one of the laminate dielectric layers and each electrically connect the third one of the metallization layers with a terminal of the semiconductor die.

Example 8. The semiconductor package of example 7, wherein a fourth one of the laminate dielectric layers is interposed between the third one of the metallization layers and a fourth one of the metallization layers, and wherein the semiconductor package further comprises at least one additional electrically conductive via that extends through the fourth one of the laminate dielectric layers and electrically connects the fourth one of the metallization layers with at least one of the plurality of electrically conductive vias that extend through the second one of the laminate dielectric layers and/or with a terminal of the semiconductor die.

Example 9. The semiconductor package of any of examples 1 through 8, wherein a first one of the laminate dielectric layers is interposed between a fifth one of the metallization layers and a lower surface of the thermally conductive substrate that is opposite the planar upper surface of the thermally conductive substrate, and wherein the semiconductor package further comprises a first plurality of thermally conductive vias that extend through the first one of the laminate dielectric layers and each thermally connect the fifth one of the metallization layers with the thermally conductive substrate.

Example 10. The semiconductor package of example 9, wherein a fifth one of the laminate dielectric layers is interposed between the fifth one of the metallization layers and a sixth one of the metallization layers, and wherein the semiconductor package further comprises a second plurality of thermally conductive vias that extend through the fifth one of the laminate dielectric layers and each thermally connect the sixth one of the metallization layers with the fifth one of the metallization layers.

Example 11. The semiconductor package of any of examples 1 through 10, wherein the thermally conductive substrate is a metal structure, wherein a lower surface of the thermally conductive substrate that is opposite the planar upper surface of the thermally conductive substrate is contacted by thermally conductive vias that dissipate heat towards a lower surface of the semiconductor package.

Example 12. The semiconductor package of any of examples 1 through 10, wherein the thermally conductive substrate comprises a ceramic layer interposed between a first substrate metallization layer and a second substrate metallization layer.

Example 13. The semiconductor package of any of examples 1 through 12, wherein a thickness of the electrically insulating thickness-matching layer is substantially the same as a thickness of the semiconductor die.

Example 14. The semiconductor package of any of examples 1 through 13, wherein a thickness of the semiconductor die is at least 200 microns.

Example 15. The semiconductor package of any of examples 1 through 14, wherein the electrically insulating thickness-matching layer is a molded layer formed of an electrically insulating mold compound.

Example 16. A method of forming a semiconductor package, the method comprising: forming a die assembly by: mounting a semiconductor die on a planar upper surface of a thermally conductive substrate, and forming an electrically insulating thickness-matching layer on the planar upper surface of the thermally conductive substrate such that the electrically insulating thickness-matching layer surrounds the semiconductor die and an upper surface of the electrically insulating thickness-matching layer is substantially coplanar with an upper surface of the semiconductor die; forming a laminate package body by stacking a plurality of laminate dielectric layers and metallization layers on top of one another; and embedding the die assembly within the laminate package body by forming a central opening through one of the laminate dielectric layers and arranging the die assembly in the central opening.

Example 17. The method of example 16, wherein the laminate package body comprises a core structure comprising a third one of the laminate dielectric layers vertically between first and second ones of the metallization layers, wherein the central opening is formed through the core structure, and wherein embedding the die assembly within the laminate package body comprises: arranging the die assembly in the central opening through the core structure such that an upper surface of the die assembly is substantially coplanar with an upper surface of the core structure, and embedding the core structure and the die assembly between a first one of the laminate dielectric layers and a second one of the laminate dielectric layers.

Example 18. The method of example 17, wherein the second one of the laminate dielectric layers is formed directly on the upper surface of the core structure and the upper surface of the die assembly.

Example 19. The method of any of examples 16 through 18, wherein the semiconductor die is configured as a lateral power transistor die, and wherein gate, source and drain terminals of the semiconductor die are disposed on the upper surface of the semiconductor die.

Example 20. The method of example 19, wherein the semiconductor die is configured as a GaN HEMT device.

Example 21. The method of any of examples 16 through 20, wherein forming the electrically insulating thickness-matching layer comprises a molding process that forms the electrically insulating thickness-matching layer as a molded layer formed of an electrically insulating mold compound.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor package, comprising:
a laminate package body comprising a plurality of laminate dielectric layers stacked on top of one another and metallization layers interposed between the laminate dielectric layers; and
a die assembly embedded within the laminate package body,
wherein the die assembly comprises:
a thermally conductive substrate that comprises a planar upper surface;
a semiconductor die mounted on the planar upper surface of the thermally conductive substrate; and
an electrically insulating thickness-matching layer formed on the planar upper surface of the thermally conductive substrate and surrounding the semiconductor die,
wherein an upper surface of the electrically insulating thickness-matching layer is substantially coplanar with an upper surface of the semiconductor die, and
wherein the upper surface of the electrically insulating thickness-matching layer and the upper surface of the semiconductor die form an upper surface of the die assembly.

2. The semiconductor package of claim 1,
wherein the laminate package body comprises a core structure embedded between a first one of the laminate dielectric layers and a second one of the laminate dielectric layers,
wherein the die assembly is arranged within a central opening in the core structure, and
wherein the upper surface of the die assembly is substantially coplanar with an upper surface of the core structure.

3. The semiconductor package of claim 2, wherein the second one of the laminate dielectric layers is formed directly on the upper surface of the core structure and the upper surface of the die assembly.

4. The semiconductor package of claim 2, wherein the core structure comprises a third one of the laminate dielectric layers vertically between first and second ones of the metallization layers.

5. The semiconductor package of claim 1, wherein the semiconductor die is configured as a lateral power transistor die, and wherein gate, source and drain terminals of the semiconductor die are disposed on the upper surface of the semiconductor die.

6. The semiconductor package of claim 5, wherein the semiconductor die is configured as a GaN HEMT device.

7. The semiconductor package of claim 1,
wherein a second one of the laminate dielectric layers is interposed between a third one of the metallization layers and the upper surface of the die assembly, and
wherein the semiconductor package further comprises a plurality of electrically conductive vias that extend through the second one of the laminate dielectric layers and each electrically connect the third one of the metallization layers with a terminal of the semiconductor die.

8. The semiconductor package of claim 7,
wherein a fourth one of the laminate dielectric layers is interposed between the third one of the metallization layers and a fourth one of the metallization layers, and
wherein the semiconductor package further comprises at least one additional electrically conductive via that extends through the fourth one of the laminate dielectric layers and electrically connects the fourth one of the metallization layers with at least one of the plurality of electrically conductive vias that extend through the second one of the laminate dielectric layers and/or with a terminal of the semiconductor die.

9. The semiconductor package of claim 1,
wherein a first one of the laminate dielectric layers is interposed between a fifth one of the metallization layers and a lower surface of the thermally conductive substrate that is opposite the planar upper surface of the thermally conductive substrate, and
wherein the semiconductor package further comprises a first plurality of thermally conductive vias that extend through the first one of the laminate dielectric layers and each thermally connect the fifth one of the metallization layers with the thermally conductive substrate.

10. The semiconductor package of claim 9,
wherein a fifth one of the laminate dielectric layers is interposed between the fifth one of the metallization layers and a sixth one of the metallization layers, and
wherein the semiconductor package further comprises a second plurality of thermally conductive vias that extend through the fifth one of the laminate dielectric layers and each thermally connect the sixth one of the metallization layers with the fifth one of the metallization layers.

11. The semiconductor package of claim 1, wherein the thermally conductive substrate is a metal structure, wherein a lower surface of the thermally conductive substrate that is opposite the planar upper surface of the thermally conductive substrate is contacted by thermally conductive vias that dissipate heat towards a lower surface of the semiconductor package.

12. The semiconductor package of claim 1, wherein the thermally conductive substrate comprises a ceramic layer interposed between a first substrate metallization layer and a second substrate metallization layer.

13. The semiconductor package of claim 1, wherein a thickness of the electrically insulating thickness-matching layer is substantially the same as a thickness of the semiconductor die plus a bond between the semiconductor die and the thermally conductive substrate.

14. The semiconductor package of claim 1, wherein a thickness of the semiconductor die is at least 200 microns.

15. The semiconductor package of claim 1, wherein the electrically insulating thickness-matching layer is a molded layer formed of an electrically insulating mold compound.

16. A method of forming a semiconductor package, the method comprising:
forming a die assembly by:
mounting a semiconductor die on a planar upper surface of a thermally conductive substrate, and
forming an electrically insulating thickness-matching layer on the planar upper surface of the thermally conductive substrate such that the electrically insulating thickness-matching layer surrounds the semiconductor die and an upper surface of the electrically insulating thickness-matching layer is substantially coplanar with an upper surface of the semiconductor die;
forming a laminate package body by stacking a plurality of laminate dielectric layers and metallization layers on top of one another; and
embedding the die assembly within the laminate package body by forming a central opening through one of the laminate dielectric layers and arranging the die assembly in the central opening.

17. The method of claim 16,
wherein the laminate package body comprises a core structure comprising a third one of the laminate dielectric layers vertically between first and second ones of the metallization layers,
wherein the central opening is formed through the core structure, and
wherein embedding the die assembly within the laminate package body comprises:
arranging the die assembly in the central opening through the core structure such that an upper surface of the die assembly is substantially coplanar with an upper surface of the core structure, and
embedding the core structure and the die assembly between a first one of the laminate dielectric layers and a second one of the laminate dielectric layers.

18. The method of claim 17, wherein the second one of the laminate dielectric layers is formed directly on the upper surface of the core structure and the upper surface of the die assembly.

19. The method of claim 16, wherein the semiconductor die is configured as a lateral power transistor die, and wherein gate, source and drain terminals of the semiconductor die are disposed on the upper surface of the semiconductor die.

20. The method of claim 19, wherein the semiconductor die is configured as a GaN HEMT device.

21. The method of claim 16, wherein forming the electrically insulating thickness-matching layer comprises a molding process that forms the electrically insulating thickness-matching layer as a molded layer formed of an electrically insulating mold compound.
